(19) United States
(12) Patent Application Publication
(10) Pub. No.: US 2013/0311849 A1
(43) Pub. Date: Nov. 21, 2013

(54) SEMICONDUCTOR DEVICE, ELECTRONIC DEVICE, ELECTRONIC SYSTEM, AND METHOD OF CONTROLLING ELECTRONIC DEVICE

(71) Applicant: Renesas Mobile Corporation, Tokyo (JP)

(72) Inventors: Kosuke Miyachi, Tokyo (JP); Kenichiro Omura, Tokyo (JP); Daisuke Kawakami, Tokyo (JP); Hiroshi Morita, Tokyo (JP)

(73) Assignee: RENESAS MOBILE CORPORATION

(21) Appl. No.: 13/898,548

(22) Filed: May 21, 2013

(30) Foreign Application Priority Data
May 21, 2012 (JP) 2012-115364

(51) Int. Cl. H03M 13/29

(52) U.S. Cl. CPC H03M 13/29
USPC 714/758

(57) ABSTRACT

A storage device holds data and error correcting codes. An LUT stores a relation between a memory address and an error correction level. An error detection level processing unit calculates, based on an access address included in an access instruction to the storage device and the LUT, the error correction level corresponding to the access address. The write controller calculates an error correcting code based on the error correction level that is calculated, and writes the error correcting code together with data in the storage device. A read controller performs error correction processing using the error correcting code based on the error correction level that is calculated, to supply data after error correction.

### CROSS-REFERENCE TO RELATED APPLICATIONS

This application is based upon and claims the benefit of priority from Japanese patent application No. 2012-115364, filed on May 21, 2012, the disclosure of which is incorporated herein in its entirety by reference.

### BACKGROUND

The present invention relates to a semiconductor device, an electronic device, an electronic system, and a method of controlling the electronic device, and for example, is suitably applicable to a memory apparatus that is capable of adding an error correcting code and a memory control method.

In recent years, a semiconductor device used in an in-vehicle system or the like has been required to have high quality and high reliability. More specifically, a semiconductor device used in an in-vehicle system or the like is required to have quality of single ppm (Parts-Per-Million) level or higher. The same quality is required also in data transfer in the semiconductor device. Accordingly, in the semiconductor device, a function of detecting and correcting an error by bit inversion is implemented in access to a memory such as a random access memory (RAM).

Japanese Unexamined Patent Application Publication No. 2009-259113 and Japanese Unexamined Patent Application Publication No. 10-285147 each disclose a technique related to a device for managing a non-volatile memory and a data transfer system including an error correction function.

### SUMMARY

The present inventors have found various problems in a process of developing a semiconductor device used in an in-vehicle system or the like and a controller controlling them, for example. Each exemplary embodiment disclosed in this application provides an electronic device and a semiconductor device suitable for the in-vehicle system or the like.

Other problems and novel features will be made apparent from the description in this specification and the accompanying drawings.

One exemplary aspect disclosed in this specification includes an electronic device, which includes a memory (storage device) and a memory controller.

According to the exemplary aspect, it is possible to provide a high-quality semiconductor device, an electronic device, various electronic systems including the electronic device, and a method of controlling the electronic device.

### BRIEF DESCRIPTION OF THE DRAWINGS

The above and other aspects, advantages and features will be more apparent from the following description of certain embodiments taken in conjunction with the accompanying drawings, in which:

FIG. 1 is a block diagram showing a configuration of an in-vehicle system equipped with an electronic device 10 according to a first exemplary embodiment;

FIG. 2 is a block diagram showing a configuration of the electronic device 10 according to the first exemplary embodiment;

FIG. 3 is a block diagram showing a configuration of a memory controller 30 according to the first exemplary embodiment;

FIG. 4 is a block diagram showing a configuration of a read controller 50 according to the first exemplary embodiment;

FIG. 5 is a block diagram showing a configuration of the read controller 50 according to the first exemplary embodiment;

FIG. 6 is a block diagram showing a configuration of a write controller 60 according to the first exemplary embodiment;

FIG. 7 is a block diagram showing a configuration of the write controller 60 according to the first exemplary embodiment;

FIG. 8 is a conceptual diagram showing an internal configuration of a management data area of a storage device 140 according to the first exemplary embodiment;

FIG. 9 is a conceptual diagram showing an internal configuration of a data holding area of the storage device 140 according to the first exemplary embodiment;

FIG. 10 is a conceptual diagram showing an internal configuration of a lookup table 72 according to the first exemplary embodiment;

FIG. 11 is a conceptual diagram showing a relation between a request address and the lookup table 72 according to the first exemplary embodiment; and

FIG. 12 is a conceptual diagram showing processing of searching the lookup table 72 by a hash processing unit 71 according to the first exemplary embodiment.

### DETAILED DESCRIPTION

### First Exemplary Embodiment

Hereinafter, with reference to the drawings, an exemplary embodiment of the present invention will be described. First, one exemplary aspect of an in-vehicle system which is one example of an electronic system which may be equipped with an electronic device according to this exemplary embodiment will be described.

<Configuration of in-Vehicle System 100 (Electronic System)>

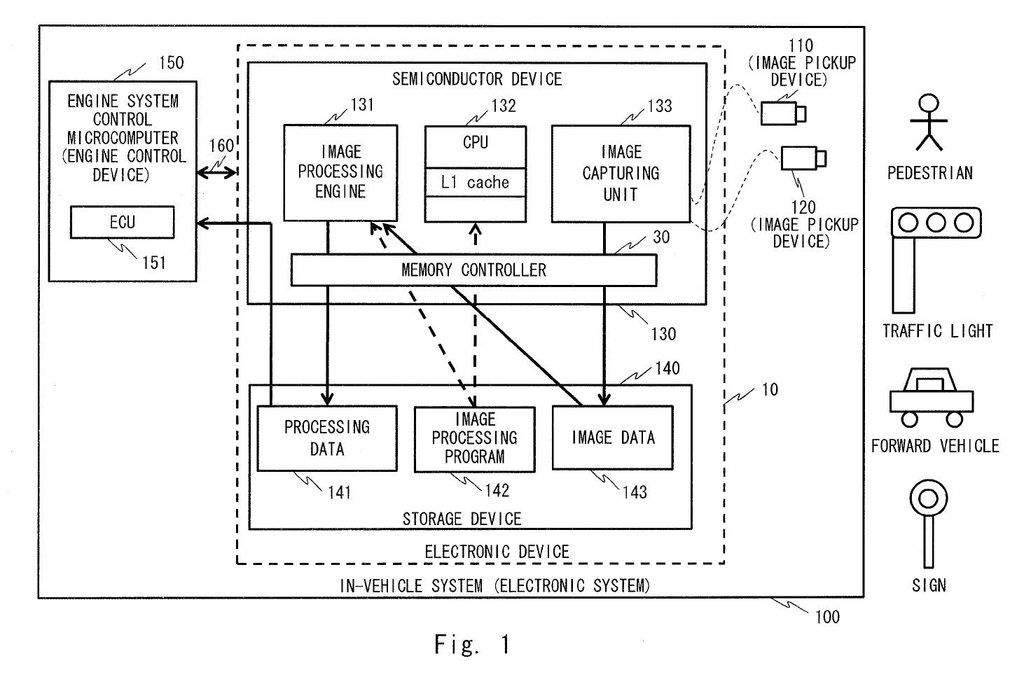

FIG. 1 is a block diagram showing a whole configuration of an in-vehicle system equipped with an electronic device 10 according to this exemplary embodiment. An in-vehicle system 100 includes a forward camera 110, a backward camera 120, the electronic device 10, and an engine system control microcomputer 150 (engine control device). The in-vehicle system 100 is an information processing system that may be installed in a general car, a car for business use (truck or the like), an automatic two-wheel vehicle (a so-called motorcycle or the like). The in-vehicle system 100 is a general term of the system that controls a dashboard and the like of the vehicle.

The forward camera 110 is a camera (image pickup device) that captures images in a front side of the vehicle provided with the in-vehicle system 100. The forward camera 110 captures images in the forward direction of the vehicle according to an instruction from an image capturing unit 133 that will be described later. As shown in FIG. 1, the imaging object may be, for example, pedestrians, traffic lights, forward vehicles, and signs. The forward camera 110 supplies the captured images (including still images and moving images) to the image capturing unit 133.

The backward camera 120 is a camera (image pickup device) that captures images in a rear side of the vehicle provided with the in-vehicle system 100. The backward camera 120 captures images in the backward direction of the vehicle according to an instruction from the image capturing unit 133 which will be described later. The imaging object includes, as shown in FIG. 1, pedestrians, traffic lights, backward vehicles, signs and the like. The backward camera 120 supplies the captured images (including still images and moving images) to the image capturing unit 133.

A semiconductor device 130 is an application system-on-a-chip (SoC) including various functions to operate each application of the in-vehicle system 100. The semiconductor device 130 includes an image processing engine 131, a central processing unit (CPU) 132, and the image capturing unit 133. The semiconductor device 130 writes various data into a storage device 140 or reads various data from the storage device 140, thereby controlling the in-vehicle system 100.

The image processing engine 131 is a processing unit that performs various image processing using images acquired by the image capturing unit 133. The image processing engine 131 reads out image data and an image processing program from the storage device 140 as appropriate, and performs various image processing on the image data that is read out. The image processing engine 131 writes data of the processing result into the storage device 140 as appropriate. As a matter of course, a part (or all) of the processing of the image processing engine 131 may be achieved as software which causes a computer to execute a program.

The CPU 132 is a central processing unit that executes various processing in the in-vehicle system 100 based on any desired program. The CPU 132 includes an L1 cache which is temporary information storage means capable of achieving faster access. The CPU 132 reads out an image processing program or an operating system (OS) program (not shown) as appropriate from the storage device 140 to execute the program. Further, the CPU 132 writes arbitrary data into the storage device 140.

The image capturing unit 133 controls image capturing processing of the forward camera 110 and the backward camera 120 according to the control from other processing units (the image processing engine 131 and the CPU 132). The image capturing unit 133 writes image data captured by the forward camera 110 and the backward camera 120 into the storage device 140.

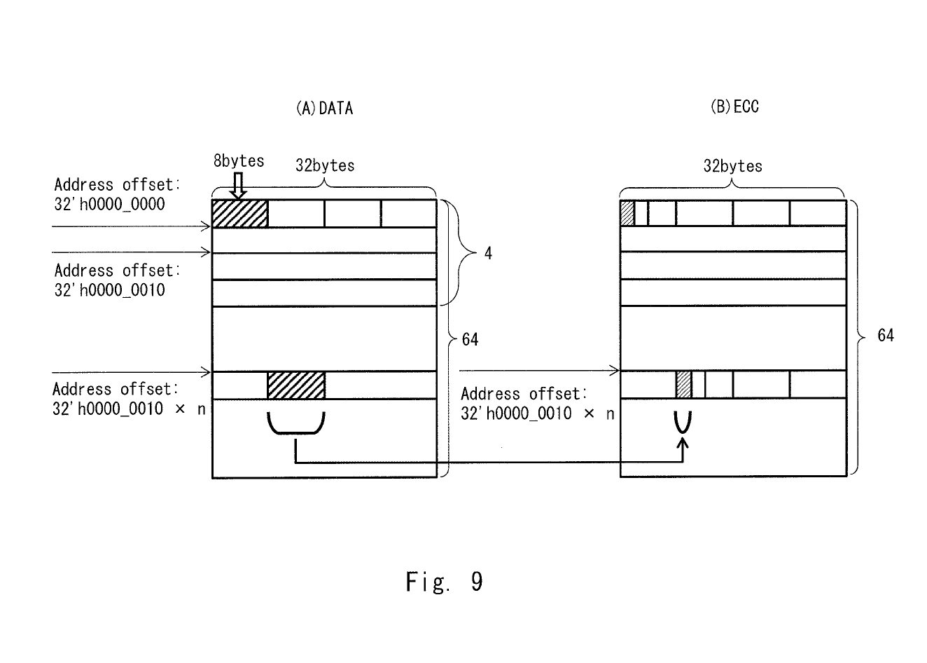

The storage device 140 is a memory apparatus that stores various data. The storage device 140 is a memory such as a DRAM. The detailed configuration of the storage device 140 will be described later with reference to FIG. 9 and the like. The storage device 140 stores, as shown in FIG. 1, various data such as processing data 141, image processing program 142, image data 143, and an OS program (not shown). The processing data 141 includes various information regarding engine control (e.g., engine speed). These data have different properties or importance. The property (importance) here indicates an index regarding how much errors in data can be tolerated when reading or writing is performed. In other words, the protection level, i.e., the accuracy of performing error correction varies depending on the properties of the data. For example, the protection level in the processing data 141 and the image processing program 142 is high, which means a data unit to add an error correcting code (ECC) is small (e.g., ECC is added for every 16 bits. The detail will be described later.) Meanwhile, the protection level in the image data 143 is low, which means there is no need to add an error correcting code (or an error correcting code may be added for a large data unit).

The engine system control microcomputer 150 (engine control device) is a microcomputer to mainly control the engine of the vehicle. The engine system control microcomputer 150 includes an engine control unit (ECU) 151.

The ECU 151 is a processing unit that controls the engine of the vehicle. More specifically, the ECU 151 performs engine control regarding brakes, acceleration, deceleration and the like. Further, the ECU 151 may perform so-called steering control. The ECU 151 appropriately reads out the processing data 141 stored in the storage device 140 via the application SoC 130 when such control is performed. The ECU 151 performs control according to the value of the processing data 141 that is read out. The ECU 151 reads out positional information or the like, for example, to perform engine control using the positional information.

An in-vehicle network 160 is a network to perform information transmission between the application SoC 130 and the engine system control microcomputer 150. The in-vehicle network 160 is achieved, for example, by a technique of controller area network (CAN) or FlexRay.

### <Configuration of Electronic Device 10>

Next, the electronic device 10 according to this exemplary embodiment will be described.

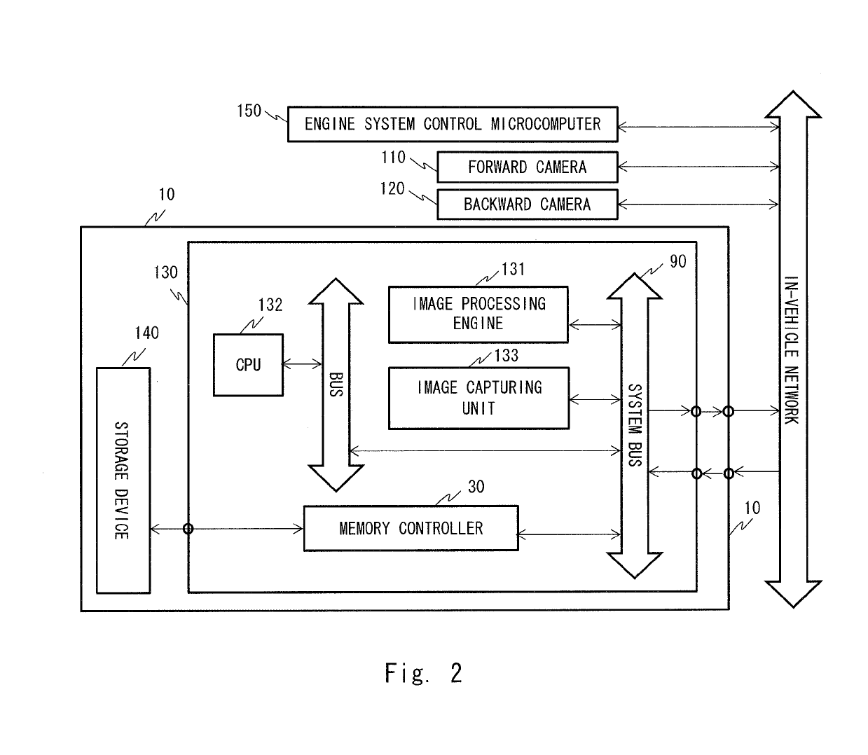

FIG. 2 is a block diagram showing the electronic device 10 according to the first exemplary embodiment. The electronic device 10 includes the semiconductor device 130 and the storage device 140. Although not particularly limited, the semiconductor device 130 and the storage device 140 are formed in a first semiconductor chip and a second semiconductor chip, respectively, and are mounted on the same wiring board. Further, the first semiconductor chip and the second semiconductor chip may be arranged in the same package.

The CPU 132 is a central processing unit that reads out necessary data or program from the storage device 140 in the electronic device 10 to perform processing. When reading data from the storage device 140, the CPU 132 issues a read request including a read address to a read controller 50 which will be described later. Further, the CPU 132 writes data indicative of the result of operation into the storage device 140 in the electronic device 10. When writing data in the storage device 140, the CPU 132 issues a write request including a write address and write data to a write controller 60 which will be described later. The details of the data reading from the storage device 140 and the data writing into the storage device 140 will be appropriately described later.

A system bus 90 is an information transmission path to perform data transmission between the CPU 132 and a memory controller 30. Further, the system bus 90 transfers various data input through the in-vehicle network to the memory controller 30, the CPU 132, and the like.

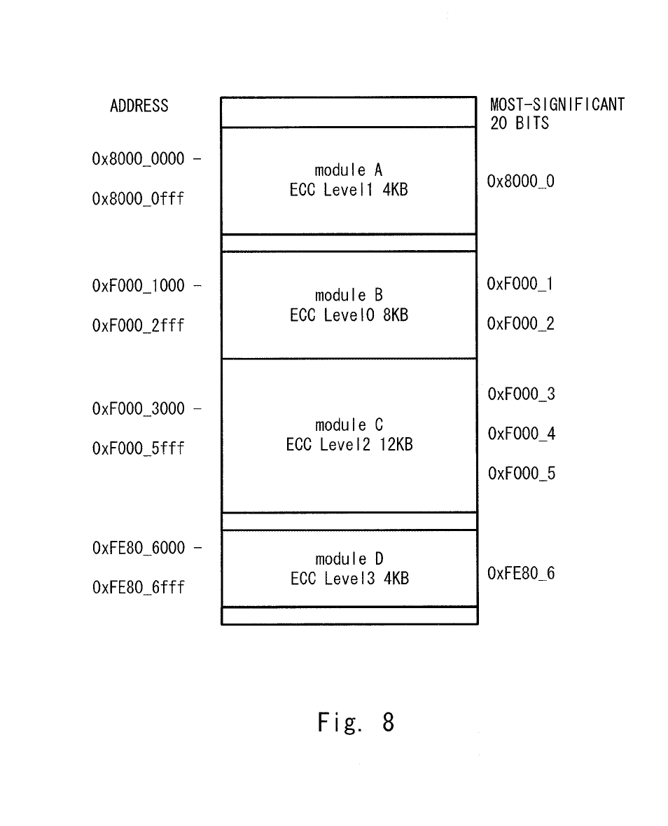

The storage device 140 stores data and programs used by the CPU 132. The storage device 140 is a volatile memory in which stored data is erased when the power of the in-vehicle system 100 is interrupted, and includes, for example, a dynamic random access memory (DRAM). A method of storing data in the storage device 140 according to this exemplary embodiment will be described later with reference to FIGS. 8 and 9.

### <Configuration of Memory Controller 30>

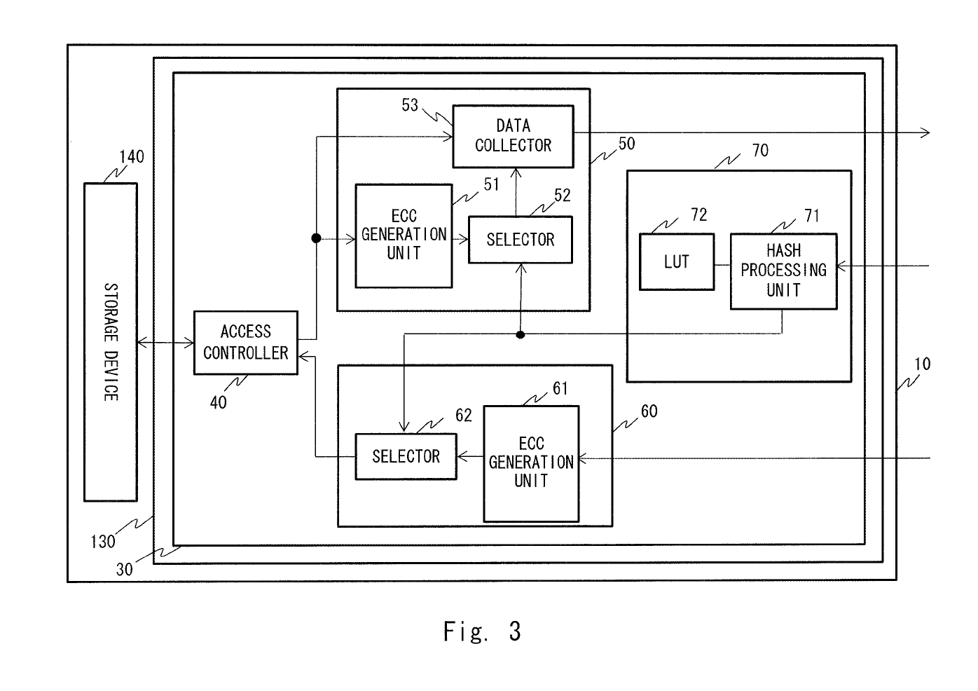

With reference to FIG. 3, a configuration of the memory controller 30 will be described. In FIG. 3, description of processing units other than the memory controller 30 in the semiconductor device 130 is omitted as appropriate. The memory controller 30 is a processing unit that controls the read request from the CPU 132 to the storage device 140 and the write request from the CPU 132 to the storage device 140. The memory controller 30 includes an access controller 40, a read controller 50, a write controller 60, and an error detection level processing unit 70.

The access controller 40 reads out data from the storage device 140 according to the read control by the read controller 50 described later to supply the data that is read out to the read controller 50. Further, the access controller 40 writes data to be written into the storage device 140 according to the write control by the write controller 60 described later.

### <Configuration of Read Controller 50>

The read controller 50 receives the read request (not shown) from the CPU 132. The read controller 50 reads out data from the storage device 140 using the read request. At this time, the read controller 50 also reads out an error correcting code (ECC) corresponding to the data that is read out. Further, the read controller 50 performs error correction processing on the data that is read out according to an error detection level supplied from the error detection level processing unit 70 which will be described later

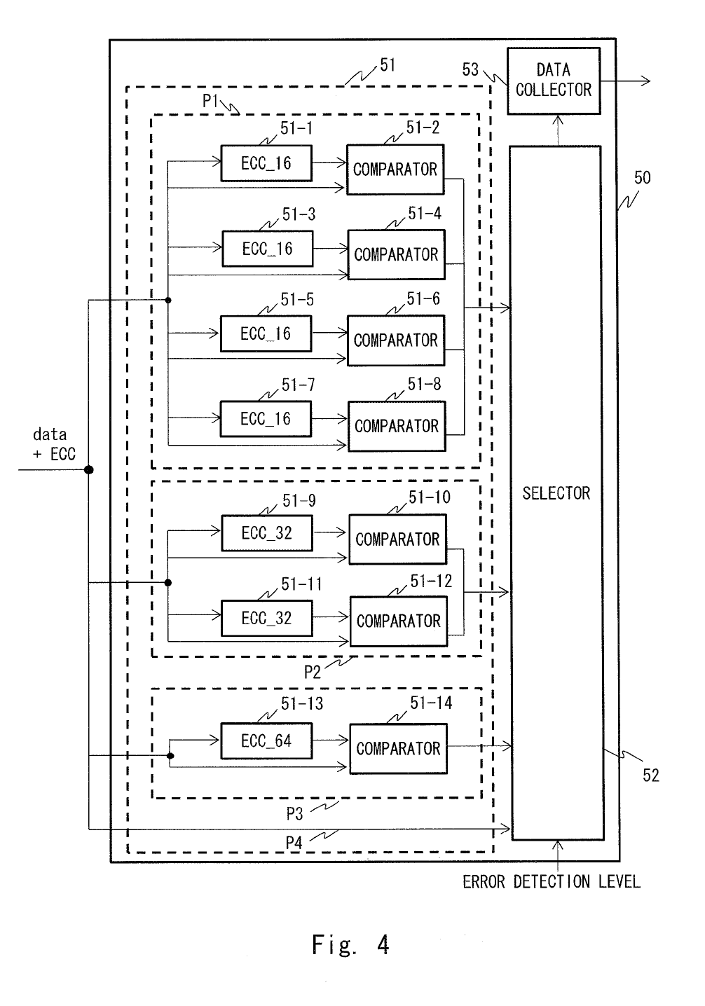

With reference to FIG. 4, a configuration of the read controller 50 will be described in detail. FIG. 4 is a block diagram showing a detailed configuration of the read controller 50 according to this exemplary embodiment. The read controller 50 includes a data comparison unit 51, a selector 52, and a data corrector 53.

The data comparison unit 51 includes, as shown in FIG. 4, a plurality of (four in FIG. 4) data paths P1 to P4. The data path P1 is a path to perform error detection processing for every 16 bits on the data that is read out from the storage device 140. An ECC_16 (ECC generation unit) 51-1 generates an ECC for every 16 bits of the data that is read out from the storage device 140. A comparator 51-2 compares the ECC read out from the storage device 140 with the ECC generated by the ECC_16 (ECC generation unit) 51-1 to supply the result of comparison to the selector 52. Other ECC_16 (ECC generation units) 51-3, 51-5, and 51-7, and comparators 51-4, 51-6, and 51-8 also perform the same processing.

The data path P2 is a path to perform error detection processing for every 32 bits on the data that is read out. An ECC_32 (ECC generation unit) 51-9 generates an ECC for every 32 bits of the data that is read out from the storage device 140. A comparator 51-10 compares the ECC read out from the storage device 140 with the ECC generated by the ECC_32 (ECC generation unit) 51-9 to supply the result of comparison to the selector 52. An ECC_32 (ECC generation unit) 51-11 and a comparator 51-12 also perform the similar processing.

The data path P3 is a path to perform error detection processing for every 64 bits on the data that is read out. An ECC_64 (ECC generation unit) 51-13 generates an ECC for every 64 bits of the data that is read out from the storage device 140. A comparator 51-14 compares the ECC read out from the storage device 140 with the ECC generated by the ECC_64 (ECC generation unit) 51-13 to supply the result of comparison to the selector 52.

The data path P4 is a path that directly supplies data read out from the storage device 140 without performing error detection processing on the data read out from the storage device 140.

The error detection level is input to the selector 52 from the error detection level processing unit 70. The selector 52 performs selection processing according to the error detection level. Specifically, the selector 52 selects read data and the ECC from one of the data paths 21 to P4 to supply the data and the ECC to the data corrector 53.

The data corrector 53 performs error correction processing using an ECC on the data received via the data paths P1 to P3, to supply the data after error correction to the CPU 132 which has made the request. Note that the data corrector 53 may perform error correction processing using an ECC using a known technique. When the data received through the data path P4 is selected, the data corrector 53 directly supplies the data to the CPU 132 without performing error correction processing.

### Variant Example of Read Controller 50

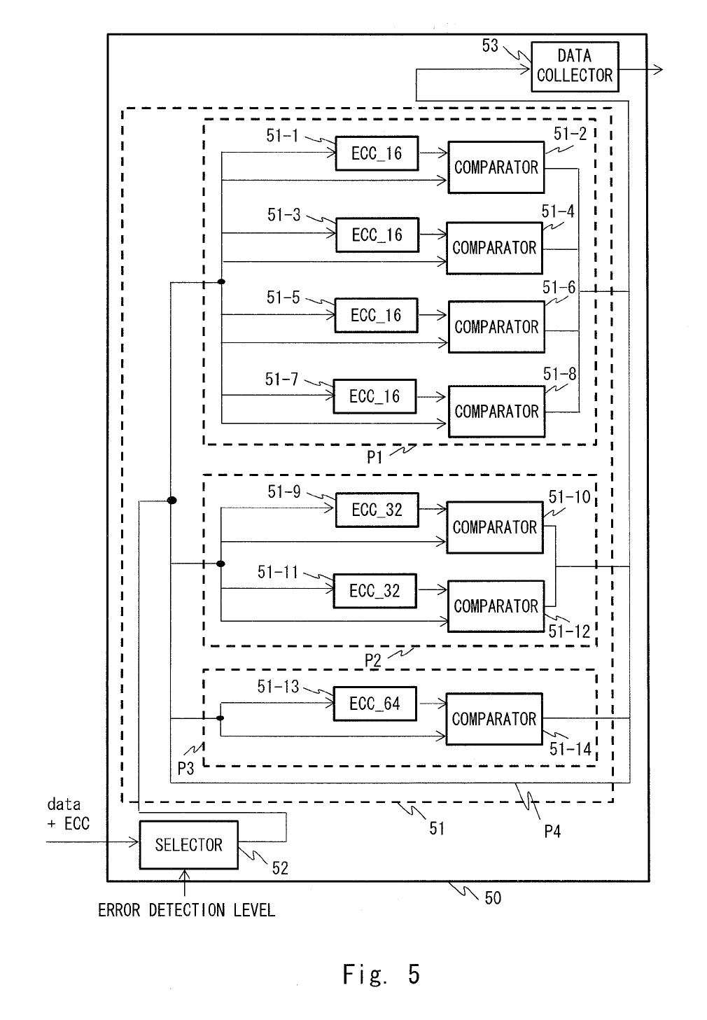

Note that the read controller 50 may be configured as shown in FIG. 5. The error detection level, and data and the ECC that are read out from the storage device 140 are input to the selector 52. The selector 52 selects one data path that corresponds to the error detection level, and supplies the read data and the ECC only to the data path that is selected. Since the configurations and the operations of the data comparison unit 51 and the data corrector 53 are similar to those shown in FIG. 4, the detailed description will be omitted.

### <Configuration of Write Controller 60>

Reference is made back again to FIG. 3. A write request (including information regarding write data and an address to which data is written) is input to the write controller 60 from the CPU 132. Further, the error detection level supplied from the error detection level processing unit 70 is supplied to the write controller 60. The write controller 60 performs control to write the ECC according to the supplied error detection level into the storage device 140 together with data.

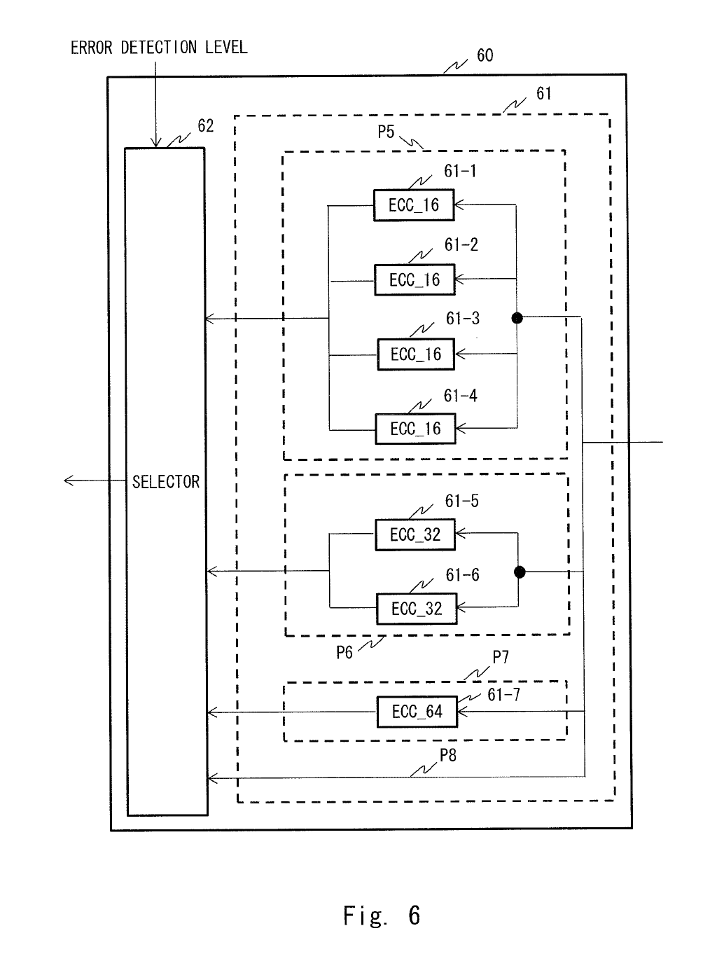

With reference to FIG. 6, a configuration of the write controller 60 will be described in detail. FIG. 6 is a block diagram showing a detailed configuration of the write controller 60 according to this exemplary embodiment. The write controller 60 includes an ECC processing unit 61 and a selector 62.

The ECC processing unit 61 includes, as shown in FIG. 6, a plurality of (four in FIG. 6) data paths P5 to P8. The data path P5 is a path to generate an ECC for every 16 bits of the data to be written. An ECC_16 (ECC generation unit) 61-1 generates an FCC for every 16 bits of the data to be written. The ECC_16 (ECC generation unit) 61-1 may generate an ECC using a technique of generating any desired error correcting code (e.g., typical hamming code, cyclic code, sparse graph code).

The ECC_16 (ECC generation unit) 61-1 supplies the ECC that is generated and 16-bit data to the selector 62. ECC_16 (ECC generation units) 61-2 to 61-4 perform the similar processing to the ECC_16 (ECC generation unit) 61-1.

The data path P6 is a path to generate an ECC for every 32 bits of the data to be written. An ECC_32 (ECC generation unit) 61-5 generates an ECC for every 32 bits of the data to be written. An ECC_32 (ECC generation unit) 61-5 supplies 32-bit data and the ECC that is generated to the selector 62. An ECC_32 (ECC generation unit) 61-6 performs the similar processing to the ECC_32 (ECC generation unit) 61-5.

The data path P7 is a path to generate an ECC for every 64 bits of the data to be written. An ECC_64 (ECC generation unit) 61-7 generates an ECC for every 64 bits of the data to be written. The ECC_64 (ECC generation unit) 61-7 supplies the ECC that is generated and 64-bit data to the selector 62.

The data path P8 is a path to write only the data into the storage device 140 without generating an ECC for data to be written.

The error detection level is input to the selector 62 from the error detection level processing unit 70. The selector 62 performs selection processing according to the error detection level. Specifically, the selector 62 selects any one of the data paths P1 to P4. Then, the selector 62 selects the write data and the ECC to supply the write data and the ECC to the access controller 40, and writes the data and the ECC in the storage device 140.

### Variant Example of Write Controller 60

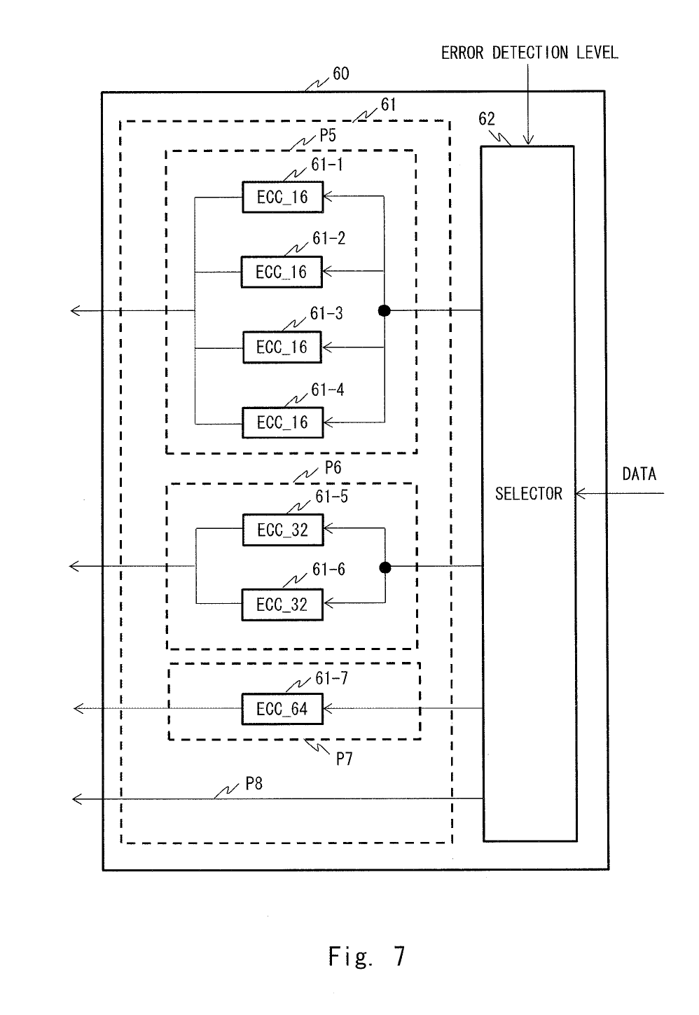

The write controller 60 may have a configuration as shown in FIG. 7. The error detection level and data to be written are supplied to the selector 62. The selector 62 selects one of the data paths P5 to P8 that corresponds to the error detection level. The selector 62 supplies data to be written only to the data path that is selected. Accordingly, data to be written and the ECC are output from only one of the paths P5 to P8. Since the configuration of the ECC processing unit 61 is similar to that shown in FIG. 6, detailed description will be omitted.

### <Data Management Method of Storage Device 140>

A data management method of the storage device 140 will be described with reference to FIGS. 8 and 9. The storage device 140 includes an area (hereinafter also referred to as a data holding area (first area)) that manages data itself (hereinafter also referred to as real data) and an ECC of the real data, and an area (hereinafter also referred to as a management data area (second area)) that holds various information (hereinafter also referred to as management data) to access the data holding area.

FIG. 8 is a conceptual diagram showing an internal configuration of the management data area of the storage device 140. The management data area of the storage device 140 is divided according to the size corresponding to the management of an operating system (OS) executed by the CPU 132. In this example, it is assumed that the management data of each module is stored in a unit of 4 KB. Specifically, the management data according to a module A is stored in addresses 0x8000_{—}0000 to 0x8000_{—}0fff. Similarly, the management data according to a module B is stored in addresses 0xF000_{—}1000 to 0xF000_{—}2fff. The management data according to a module C is stored in addresses 0xF000_{—}3000 to 0xF000_{—}5fff. The management data according to a module D is stored in addresses 0xFE80_{—}6000 to 0xzFE80_{—}6fff.

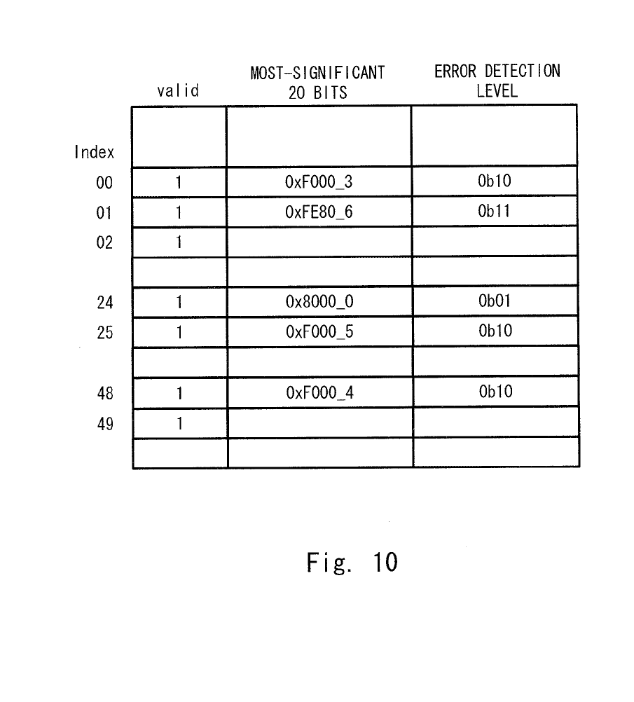

An address (address (32′h0000_{—}0000) shown in FIG. 10 described later) or the like for the data holding area (area that holds the ECC and the real data of the module A) is stored in each management data (e.g., management data according to the module A). The address of the read request and the address of the write request issued by the CPU 132 or the like specify the address (ex. 0x8000_{—}0000) of the management data. However, since data is managed in a unit of 4 KB as stated above, it is possible to determine the area to be accessed if only the most significant 20 bits (ex. 0x80000_{—}0x80001) of the address can be known.

FIG. 9 is a conceptual diagram showing a data holding area of the storage device 140. The storage device 140 holds real data by dividing the real data into 8 bytes, which is a predetermined unit. The storage device 140 holds the read data by associating 8-byte real data with one byte of an ECC of the real data. In summary, real data and an ECC are associated in a predetermined bit ratio. The information of an address offset indicating the start position of the real data is included in the management data.

By allocating data (associating the real data and with ECC in a predetermined bit ratio) as shown in FIG. 9, reading and writing can be performed in a fixed data unit. Accordingly, it is possible to increase the data access speed.

### <Configuration of Error Detection Level Processing Unit 70>

Reference is again made back to FIG. 3. The error detection level processing unit 70 receives the read request or the write request from the CPU 132, and generates the error detection level stated above according to the received request (address included in the request). The error detection level is information indicating for specifying which bit number of ECC processing is to be executed on the read/write data (for every which bit error correction processing by the ECC is to be performed/the number of bits for which each ECC is added), or ECC processing is not performed. In the examples shown in FIGS. 4 to 7, the error detection level may be four levels of (1) ECC processing is not performed, (2) ECC processing is performed for every 16 bits, (3) ECC processing is performed for every 32 bits, and (4) ECC processing is performed for every 64 bits. In this example, the error detection level may be “0b00”(1), “0b01”(2), “0b10”(3), and “0b11” (4) in order. The error detection level processing unit 70 supplies the error detection level that is generated to the selector 52 in the read controller 50 and the selector 62 in the write controller 60. Hereinafter, the detail will be described.

The error detection level processing unit 70 includes a hash processing unit 71 and a lookup table 72. First, with reference to FIG. 10, a configuration of the lookup table 72 in the error detection level processing unit 70 will be described.

### <Configuration of Lookup Table 72>

The lookup table 72 is a data table storing a valid flag, the most significant 20 bits, and the error detection level. An index (1—in FIG. 10) to identify the data column is added to the lookup table 72.

The valid flag is information indicating whether the data column is valid. When 1 is set in the valid flag, it means that the data column is valid. When 0 is set in the valid flag, it means that the data column is invalid. When 0 (invalid) is set, it is regarded that data indicating that ECC is not generated (“0b00”) is set to the error detection level. The most significant 20 bits indicate the values of the most significant 20 bits of the address of the read request or the write request. The error detection level is information that indicates the error correction level (generating an ECC in a unit of 64 bits, generating an ECC in a unit of 32 bits, or generating an ECC in a unit of 16). The error detection level is set so as not to include the data indicating that ECC is not generated (“0b00”). In this way, it is possible to reduce the capacity of the lookup table 72.

### <Hash Processing>

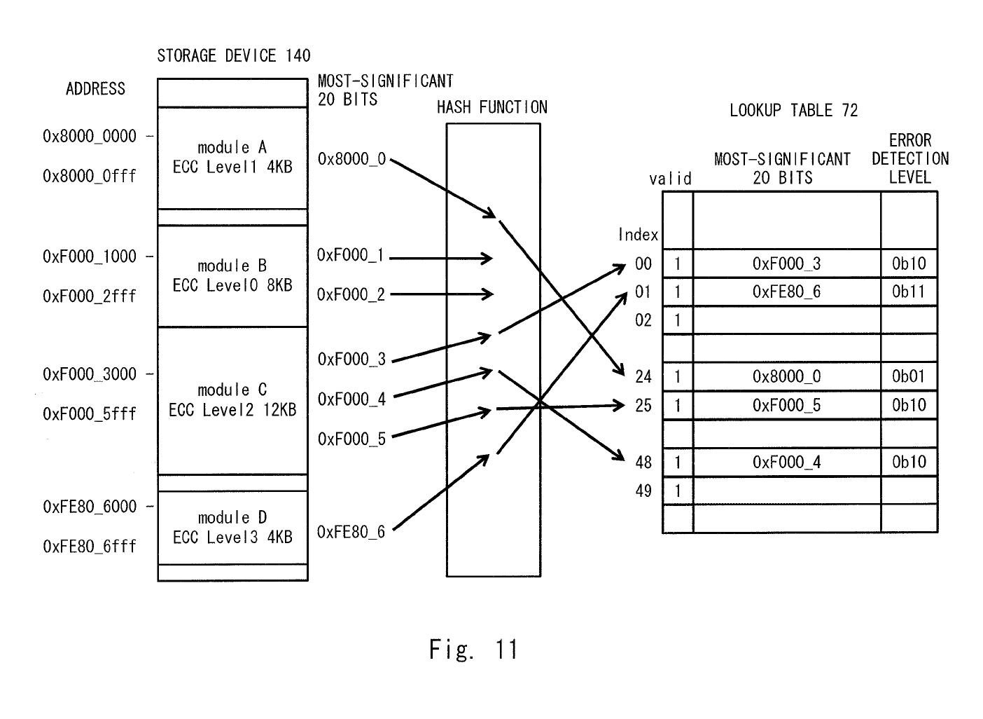

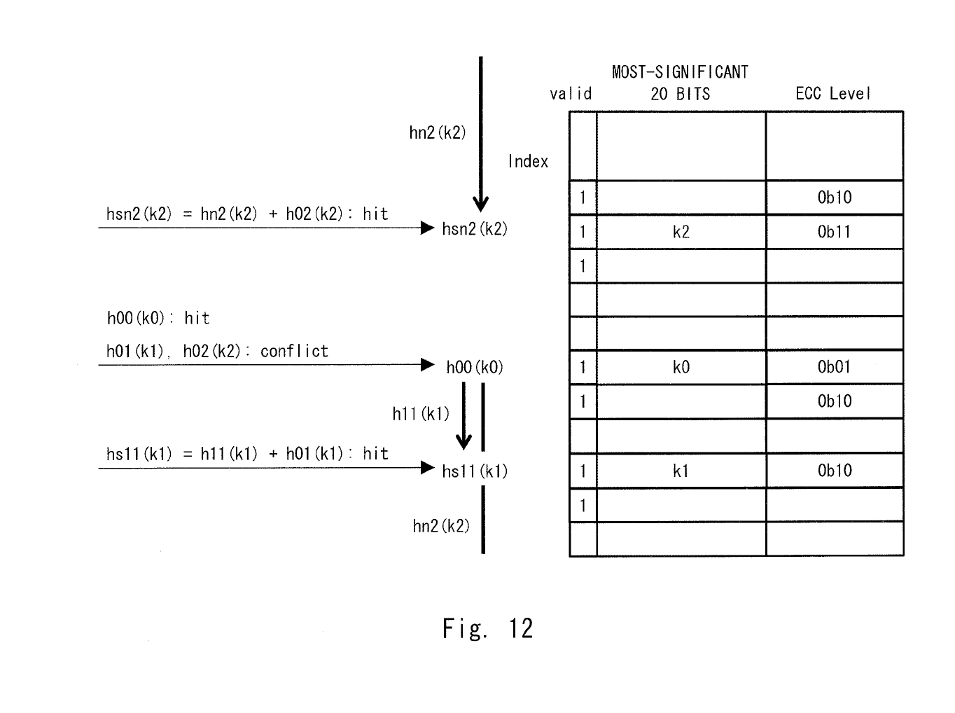

The hash processing unit 71 calculates an index to access the lookup table 72, and accesses the lookup table 72 to determine the error detection level supplied to the read controller 50 and the write controller 60. Hereinafter, with reference to FIGS. 11 and 12, the outline of processing by the hash processing unit 71 will be described.

FIG. 11 is a conceptual diagram showing a relation between the address of the read request or the write request and the lookup table 72. With reference to FIG. 11, schematic processing of the hash processing unit 71 will be described.

The hash processing unit 71 reads out the most significant 20 bits of the address of the read request or the write request. The hash processing unit 71 substitutes the most significant 20 bits into a hash function which will be described later, to determine the index which is a search position of the lookup table 72. The hash processing unit 71 determines whether the same values of the most significant 20 bits are set in the index that is determined.

When the same values of the most significant 20 bits are set, the hash processing unit 71 acquires the error detection level from the table column of this index. The hash processing unit 71 then supplies the error detection level that is acquired to the read controller 50 or the write controller 60.

Meanwhile, when the same values of the most significant 20 bits are not set in the index in the search position, the hash processing unit 71 calculates an index indicating another search position using the hash function to perform determination again. After a predetermined number of conflicts (a state in which a data column including the values of the most significant 20 bits same to the most significant 20 bits of the input address cannot be found), the hash processing unit 71 ends the search. When the search is ended in a state of conflict, the hash processing unit 71 supplies the error detection level “0b00” indicating that ECC processing is not performed to the read controller 50 or the write controller 60.

Next, with reference to FIG. 12, the detail of processing of searching the lookup table 72 by the hash processing unit 71 will be described. FIG. 12 is a conceptual diagram showing a search concept of the lookup table 72. In this example, open addressing double hashing is used as a processing logic of hash. Note that the processing logic of hash is not limited to the open addressing double hashing, but other logics may be used.

The hash processing unit 71 determines the search position using the following (Expression 1).

hₛₙₘ(kₘ)=hₙₘ(kₘ)+h₀ₘ(kₘ) [Expression 1]

hₙₘ(kₘ)=kₘ % cₙ
h₀ₘ(kₘ)=kₘ % B
h₀ₘ(kₘ): index to be searched (no conflict)
hₛₙₘ(kₘ): index to be searched (n-th time after conflict)
hₙₘ(kₘ): search width in n-th time
kₘ: most sign cant 20 bits of address
B: depth of LUT (prime number)
   cₙ: prime number equal to or smaller than B (n-th
search after conflict)

Hereinafter, detailed search procedures will be described.

(1) The hash processing unit 71 calculates, from (Expression 2) included in the (Expression 1) stated above, an index to be accessed first.

h₀ₘ(kₘ)=kₘ % B [Expression 2]

(2) The hash processing unit 71 sets the index calculated in the (Expression 2) as a search position to acquire data from the lookup table 72, thereby determining whether the most significant 20 bits that are acquired match the most significant 20 bits of the address included in the request. When they are matched, the hash processing unit 71 determines that this search is hit. In the case of hit, the hash processing unit 71 acquires the error detection level from the index of the lookup table 72.

(3) When the search is not hit but conflict, the hash processing unit 71 calculates the next search position from (Expression 3) included in the (Expression 1) stated above.

$${h}_{s n m} ( {k}_{m} ) = {h}_{n m} ( {k}_{m} ) + {h}_{0 m} ( {k}_{m} ) ( n - t h search ) \\ {h}_{n m} ( {k}_{m} ) = {k}_{m} \% {c}_{n} ( \begin{matrix}moving distance from \\ first search position\end{matrix} ) \\ {h}_{0 m} ( {k}_{m} ) = {k}_{m} \% B ( first search position ) \qquad [ Expression 3 ]$$

(4) The hash processing unit 71 sets the index calculated in the (Expression 3) as the search position to acquire data from the lookup table 72, thereby determining whether the most significant 20 bits that are acquired match the most significant 20 bits of the address included in the request. When they are matched, the hash processing unit 71 determines that this search is hit. In the case of hit, the hash processing unit 71 acquires the error detection level from the index of the lookup table 72.

(5) When the search is not hit but conflict, the hash processing unit 71 calculates the next search position from (Expression 4) included in the (Expression 1) shown above. The hash processing unit 71 repeats the process of (5) for a predetermined number of times until the search results in hit. When the search does not result in hit even after a predetermined number of searches, the hash processing unit 71 supplies the error detection level “0b00” (value indicating that ECC processing is not performed) to the read controller 50 or the write controller 60.

hₛₙₘ(kₘ)=hₙₘ(kₘ)+h₀ₘ(kₘ) [Expression 4]

Next, hash processing will be described using specific data examples. In the following description, each data is defined as shown in the following (Expression 5).

B=1013,c₁=997,c₂=971 [Expression 5]

When the most significant 20 bits of the address are 0x04E20 (0d20000), the hash processing unit 71 performs calculation processing as shown in the following (Expression 6) to determine the index which is the search position.

0x04E20 mod 1013=753 [Expression 6]

In this example, it is assumed that the most significant 20-bit address “0x04E20” is stored in an index 753 of the lookup table 72. The hash processing unit 71 reads out the error detection level from the index 753 of the lookup table 72 and supplies the error detection level to the read controller 50 or the write controller 60.

Subsequently, consider that a request in which the most significant 20 bits of the address are 0x0560A (0d22026) is processed. The hash processing unit 71 performs calculation processing as shown in the following (Expression 7), to determine the index which is the search position.

0x0560A mod 1013=753 [Expression 7]

However, the most significant 20-bit address “0x04E20” is stored in the index 753 of the lookup table 72. Accordingly, the hash processing unit 71 determines that this search is conflict. The hash processing unit 71 performs calculation processing as shown in the following (Expression 8), to determine the index which is the re-search position.

0x0560A mod 997=92 [Expression 8]

Index845 (753+92) (searched address)

In this example, it is assumed that the most significant 20-bit address “0x0560A” is stored in an index 845 of the lookup table 72. The hash processing unit 71 reads out the error detection level from the index 845 of the lookup table 72 and supplies the error detection level to the read controller 50 or the write controller 60.

Subsequently, consider that a request in which the most significant 20 bits of the address are 0xFBF33 (0d1031987) is processed. The hash processing unit 71 performs calculation processing as shown in the following (Expression 9), to determine the index which is the search position.

0xFBF33 mod 1013=753 [Expression 9]

However, the most significant 20-bit address “0x04E20” is stored in the index 753 of the lookup table 72. Accordingly, the hash processing unit 71 determines that this search is conflict. The hash processing unit 71 performs calculation processing as shown in the following (Expression 10), to determine the index which is the re-search position.

0x0560A mod 997=92 [Expression 10]

Index 845 (753+92) (searched address)

However, the most significant 20-bit address “0x0560A” is stored in the index 845 of the lookup table 72. Accordingly, the hash processing unit 71 determines that this search is conflict. The hash processing unit 71 performs calculation processing as shown in the following (Expression 11), to determine again the index which is the re-search position.

$$0 \times F B F 33 mod 971 = 785 \\ Index 525 ( 753 + 785 = 1538 , 1538 mod 1013 = 525 ) ( searched address ) \qquad [ Expression 11 ]$$

The hash processing unit 71 searches for an index 525 of the lookup table 72. When the search is hit, the hash processing unit 71 acquires the error detection level. When the search is not hit (in the case of conflict), the hash processing unit 71 continues to perform re-searching up to a predetermined number of times.

The number of times required to search the lookup table 72 is determined according to the depth of the lookup table (B shown above). When the depth of the lookup table is increased, the number of times of search can be decreased. For example, when the depth (B) of the lookup table is 1013 as stated above, up to three searches are required, whereas when the depth (B) of the lookup table is 2026, up to two searches are required. The hash processing unit 71 may determine the number of times of search as a condition by referring to the relation with the depth of the lookup table 72.

### <Effects>

Next, the effects of the electronic device 10 according to this exemplary embodiment will be described. First, for comparison to the electronic device 10 according to this exemplary embodiment, a non-volatile memory apparatus disclosed in Patent literature 1 will be described. This non-volatile memory apparatus changes the length of data input to or output from a non-volatile memory according to an address to a memory. However, the non-volatile memory apparatus does not manage data according to a management unit of a control device (to be exact, an OS on which a CPU that writes/reads data into/from a memory operates). Further, the non-volatile memory apparatus does not consider that an error correcting code is not added.

Meanwhile, the electronic device 10 according to this exemplary embodiment manages each data for each management unit of the OS, as shown in FIG. 8. Accordingly, it is possible to achieve easy data access from the OS, in particular, improvement in access speed. Furthermore, the electronic device 10 according to this exemplary embodiment also considers, as shown in P4 in FIG. 4 and P8 in FIG. 6, a configuration in which an error correcting code (ECC) is not treated. Accordingly, it is possible to quickly read/write data which is less important from/into the storage device 140, and to reduce the size of the data stored in the storage device 140.

Furthermore, the electronic device 10 according to this exemplary embodiment is able to easily set the error detection level of each data by use of the lookup table 72. In summary, it is possible to easily set the importance of data, and to protect data according to the importance (error detection level). Further, by providing a valid bit in the lookup table 72, it is possible to change the error detection level at any desired timing during the operation of the electronic device 10.

The lookup table 72 does not include data indicating that an ECC is not generated (“0b00”), as described above. Accordingly, the lookup table 72 stores only a minimum amount of data. Accordingly, it is possible to reduce the size of the lookup table 72.

Further, when the search does not result in hit even after a predetermined number of searches, the hash processing unit 71 regards that data indicating that ECC is not generated (“0b00”) is set. Accordingly, it is possible to prevent an exhaustive search of the lookup table 72 by the hash processing unit 71, thereby being able to improve the processing speed.

Furthermore, the storage device 140 associates the area that stores data with the area that stores ECCs (error correcting codes) in a constant bit rate (in the example shown in FIG. 9, 8 bytes-1 bytes), as shown in FIG. 9. Accordingly, the corresponding relationship of data becomes simple and it is possible to improve the speed to write/read data to/from the storage device 140.

Further, as described above, open addressing double hashing is used, for example, as a hash logic. By employing such a simple configuration, it is possible to simplify the circuit and to increase the processing speed.

While the invention made by the present inventors has been described in detail based on the exemplary embodiment, the present invention is not limited to the exemplary embodiment stated above, but may be changed as a matter of course in various ways without departing from the spirit of the present invention. For example, while description has been made above assuming the case of RAM, it is not limited to it. The storage device 140 is not limited to a RAM such as a dynamic random access memory (DRAM). Further, the storage device 140 is not necessarily a volatile memory but may be a non-volatile memory that retains stored data even after power is off. In summary, the memory arranged in the electronic device may be a desired storage device which can perform reading and writing operations.

While described above is the case in which the memory apparatus according to the present invention is installed in an in-vehicle system, the memory apparatus according to the present invention may be installed in any another information processing system. For example, it is needless to say that the memory apparatus according to the exemplary embodiment may be used for a control system or the like of an industrial robot.

While the invention has been described in terms of several embodiments, those skilled in the art will recognize that the invention can be practiced with various modifications within the spirit and scope of the appended claims and the invention is not limited to the examples described above.

Further, the scope of the claims is not limited by the embodiments described above.

Furthermore, it is noted that, Applicant's intent is to encompass equivalents of all claim elements, even if amended later during prosecution.

What is claimed is:

1. An electronic device comprising:
(a) a storage device comprising:
(i) a first area that stores data and an error correcting code of the data; and
(ii) a second area that stores management data for managing the first area for each control unit of an arithmetic unit, and
(b) a semiconductor device that controls the storage device, the semiconductor device comprising:
(i) an error detection level processing unit that includes a lookup table for storing a relation between a memory address and an error correction level and calculates an error correction level corresponding to an access address based on the access address included in an access instruction to a memory and the lookup table;
(ii) a write controller that determines, based on the error correction level calculated by the error detection level processing unit, whether to add an error correcting code for each unit size of write data and the unit size when the error correcting code is added, and writes the write data and an error correcting code corresponding to the data into the second area according to the management data in the first area; and
(iii) a read controller that acquires data and the error correcting code from the second area based on the management data in the first area and performs error correction of the acquired data based on the error correction level calculated by the error detection level processing unit.

2. The electronic device according to claim 1, wherein the error detection level processing unit comprises a hash processing unit that calculates a search position of the lookup table by substituting the access address included in the access instruction into a predetermined hash function, and reads out an error correction level in a data column in case of a hit state in which a memory address included in the data column of the search position matches the access address substituted into the hash function.

3. The electronic device according to claim 1, wherein the lookup table does not hold a value indicating a correction level which indicates that error correction is not performed as the error correction level.

4. The electronic device according to claim 3, wherein, when search does not result in a hit state after performing the search of the lookup table for a predetermined number of times using the hash function, the hash processing unit regards that the correction level indicating that the error correction is not performed is set as the error correction level.

5. The electronic device according to claim 1, wherein:
the storage device comprises a code storage area that stores a data storage area for storing data and the error correcting code in the first area, and
the data storage area and the code storage area are associated with each other in a predetermined bit rate.

6. The electronic device according to claim 1, wherein the lookup table further comprises information of a valid flag indicating validity of each data column in a table.

7. The electronic device according to claim 2, wherein the error detection level processing unit performs an operation of open addressing double hashing as an operation using the hash function.

8. A method of controlling an electronic device comprising a storage device comprising a first area that stores data and an error correcting code of the data and a second area that stores management data for managing the first area for each control unit of an arithmetic unit, the method comprising:
(a) including a lookup table that stores a relation between a memory address and an error correction level and calculating an error correction level corresponding to an access address based on the access address included in an access instruction to a memory and the lookup table; and
(b) determining, based on the error correction level that is calculated, whether to add an error correcting code for each unit size of write data and the unit size when the error correcting code is added, and writing the write data and an error correcting code corresponding to the data into the second area according to the management data in the first area; and
(c) acquiring data and the error correcting code from the second area based on the management data in the first area and performing error correction of the acquired data based on the error correction level calculated by the error detection level processing unit.

9. The method of controlling the electronic device according to claim 8, comprising calculating a search position of the lookup table by substituting the access address included in the access instruction into a predetermined hash function, and reading out an error correction level in a data column in case of a hit state in which a memory address included in the data column of the search position matches the access address substituted into the hash function.

10. The method of controlling the electronic device according to claim 8, wherein the lookup table does not hold a value indicating a correction level which indicates that error correction is not performed as the error correction level.

11. The method of controlling the electronic device according to claim 10, wherein, when search does not result in a hit state after performing the search of the lookup table for a predetermined number of times using the hash function, it is regarded that the correction level indicating that the error correction is not performed is set as the error correction level.

12. The method of controlling the electronic device according to claim 8, wherein:
the storage device comprises a code storage area that stores a data storage area for storing data and the error correcting code in the first area, and
the data storage area and the code storage area are associated with each other in a predetermined bit rate.

13. The method of controlling the electronic device according to claim 8, wherein the lookup table further comprises information of a valid flag indicating validity of each data column in a table.

14. The method of controlling the electronic device according to claim 9, comprising performing an operation of open addressing double hashing as an operation using the hash function.

15. A semiconductor device that controls a storage device comprising a first area that stores data and an error correcting code of the data and a second area that stores management data for managing the first area for each control unit of an arithmetic unit, the semiconductor device comprising:
(a) an error detection level processing unit that includes a lookup table for storing a relation between a memory address and an error correction level and calculates an error correction level corresponding to an access address based on the access address included in an access instruction to a memory and the lookup table;
(b) a write controller that determines, based on the error correction level calculated by the error detection level processing unit, whether to add an error correcting code for each unit size of write data and the unit size when the error correcting code is added, and writes the write data and an error correcting code corresponding to the data into the second area according to the management data in the first area; and
(c) a read controller that acquires data and the error correcting code from the second area based on the management data in the first area and performs error correction of the acquired data based on the error correction level calculated by the error detection level processing unit.

16. An electronic system comprising:
(a) an image pickup device;
(b) a storage device that stores image data acquired by the image pickup device; the storage device comprising:
(i) a first area that stores data and an error correcting code of the data; and
(ii) a second area that stores management data for managing the first area for each control unit of an arithmetic unit; and
(c) a semiconductor device that controls the storage device, the semiconductor device comprising:
(i) an error detection level processing unit that includes a lookup table for storing a relation between a memory address and an error correction level and calculates an error correction level corresponding to an access address based on the access address included in an access instruction to a memory and the lookup table;
(ii) a write controller that determines, based on the error correction level calculated by the error detection level processing unit, whether to add an error correcting code for each unit size of write data and the unit size when the error correcting code is added, and writes the write data and an error correcting code corresponding to the data into the second area according to the management data in the first area; and
(iii) a read controller that acquires data and the error correcting code from the second area based on the management data in the first area and performs error correction of the acquired data based on the error correction level calculated by the error detection level processing unit.

17. The electronic system according to claim 16, wherein:
the electronic system is used for in-vehicle use, and further comprises (d) an engine control device, and
the engine control device controls an engine based on data stored in the storage device.
